(19) United States
(12) Patent Application Publication
(10) Pub. No.: US 2008/0181267 A1
(43) Pub. Date: Jul. 31, 2008

(54) OPTICAL DEVICE AND METHOD FOR MANUFACTURING THE SAME

(75) Inventors: Yasutaka IMAI, Suwa-shi (JP); Masamitsu MOCHIZUKI, Chima-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/020,912

(22) Filed: Jan. 28, 2008

(30) Foreign Application Priority Data
Jan. 31, 2007 (JP) 2007-021029

(51) Int. Cl. H01S 5/026

(52) U.S. Cl. 372/29.011; 438/24; 257/E33.076

(57) ABSTRACT

An optical device, including: a surface emitting semiconductor laser; and a photodetection device for detecting part of laser light emitted from the surface emitting semiconductor laser; the photodetection device including a light absorbing layer and a first contact layer; and the first contact layer being formed with a semiconductor having an absorption edge wavelength smaller than an oscillation wavelength of the surface emitting semiconductor laser.

The entire disclosure of Japenese Patent Application No. 2007-021029, filed Jan. 31, 2007 is expressly incorporated by reference herein.

### BACKGROUND

1. Technical Field

The present invention relates to an optical device and a manufacturing method thereof.

2. Related Art

Surface emitting semiconductor lasers have a characteristic of the optical outputs fluctuating depending on the conditions such as an ambient temperature. Optical devices using the surface emitting semiconductor lasers may include photodetection devices for detecting part of the laser light emitted from the surface emitting semiconductor lasers, the laser light being detected as an optical output. Such photodetection devices absorb laser light, and the absorbed light becomes hole-electron pairs by applying a reverse bias voltage to a photo diode, thereby the laser light is detected as a monitor current. For instance, JP-A-2000-269585 discloses an optical transceiver module having a photodetection device being integrated on a surface emitting laser.

However, not all the hole-electron pairs generated in the photodetection devices are converted into monitor currents in the surface emitting semiconductor lasers provided with photodetection devices. Some hole-electron pairs are not converted to monitor currents. Such hole-electron pairs are recombined so as to be converted to thermal energy. The converted thermal energy increases the temperature of the active layer of the surface emitting semiconductor laser, thereby deteriorating the light-emitting property of the surface emitting semiconductor laser.

### SUMMARY

An advantage of the invention is to provide an optical device which allows to inhibit the deterioration of a light-emitting property of a surface emitting semiconductor laser, as well as to provide a method for manufacturing the optical device.

According to a first aspect of the invention, an optical device includes: a surface emitting semiconductor laser; and a photodetection device for detecting part of laser light emitted from the surface emitting semiconductor laser. Here, the photodetection device includes a light absorbing layer and a first contact layer, and the first contact layer is formed with a semiconductor having an absorption edge wavelength smaller than an oscillation wavelength of the surface emitting semiconductor laser.

In the description according to the aspect of the invention, the term “superjacent” is used in phrases such as “forming a specific thing (hereafter referred to as “A”) superjacent to another specific thing (hereafter referred to as “B”). The phrase in this example includes both cases of forming B directly on A, as well as forming B over A having another thing therebetween.

The “oscillation wavelength” according to the aspect of the invention means a wavelength of light at its maximum intensity predicted in a design stage of the optical device, the light being emitted from the surface emitting semiconductor laser.

Here, the concept of “light absorbing layer” includes a depletion layer.

In this case, the first contact layer may be provided closer to the surface emitting semiconductor laser relative to the light absorbing layer.

In this case, the photodetection device may further include a second contact layer provided facing the first contact layer, having the light absorbing layer therebetween, and the second contact layer may be formed with a semiconductor having the absorption edge wavelength thereof being smaller than the oscillation wavelength of the surface emitting semiconductor laser.

In this case, the photodetection device may further include an electrode in contact with the first contact layer, and the first contact layer may be formed with a material allowing an ohmic contact with the electrode.

In optical device according to the first aspect of the invention, the first contact layer may be formed with aluminum gallium arsenide (AlGaAs) if the oscillation wavelength of the surface emitting semiconductor laser is 850 nm.

In this case, the first contact layer may be formed with AlₓGa₁₋ₓAs, where x is greater than or equal to 0.035.

In this case, the first contact layer may also be formed with AlxGa₁₋ₓAs, where x is between 0.035 and 0.15 inclusive.

In optical device according to the first aspect of the invention, the surface emitting semiconductor laser may include a first mirror formed superjacent to the surface emitting semiconductor laser, an active layer formed superjacent to the first mirror, and a second mirror formed superjacent to the active layer. The photodetection device may include the first contact layer formed superjacent to the second mirror, the light absorbing layer formed superjacent to the first contact layer, and the second contact layer formed superjacent to the light absorbing layer.

In this case, the optical device may further include an isolation layer formed between the surface emitting semiconductor laser and the photodetection device. Here, the isolation layer contains a semiconductor having the absorption edge wavelength smaller than the oscillation wavelength of the surface emitting semiconductor laser.

In the optical device according to the first aspect of the invention, the photodetection device includes: the second contact layer; the light absorbing layer formed superjacent to the second contact layer; and the first contact layer formed superjacent to the light absorbing layer. At the same time, the surface emitting semiconductor laser includes: the first mirror formed superjacent to the first contact layer; the active layer formed superjacent to the first mirror; and the second mirror formed superjacent to the active layer.

According to a second aspect of the invention, an optical device includes: a surface emitting semiconductor laser; and a photodetection device for detecting part of laser light emitted from the surface emitting semiconductor laser. Here, the photodetection device includes a light absorbing layer and a first contact layer, and the first contact layer is formed with a semiconductor transparent to an oscillation wavelength of the surface emitting semiconductor laser.

According to a third aspect of the invention, a method for manufacturing an optical device including a surface emitting semiconductor laser and a photodetection device for detecting part of laser light emitted from the surface emitting semiconductor laser, the method includes: forming the surface emitting semiconductor laser; forming a first contact layer for constituting the photodetection device, using a semiconductor having an absorption edge wavelength smaller than an oscillation wavelength of the surface emitting semiconductor laser; and forming a light absorbing layer, using a semiconductor which absorbs light from the surface emitting semiconductor laser.

### BRIEF DESCRIPTION OF THE DRAWINGS

The invention will be described with reference to the accompanying drawings, wherein like numbers reference like elements.

FIG. 1 is a sectional drawing schematically showing an optical device according to an embodiment.

FIG. 2 is a drawing showing a dependency of an absorption edge wavelength of AlₓGa₁₋ₓAs, on an Al composition.

FIG. 3 is a drawing illustrating monitor current characteristics of an optical device according to an embodiment.

FIG. 4 is a drawing illustrating an active layer temperature of an optical device according to an embodiment.

FIG. 5 is a drawing illustrating dependencies of a monitor current and an optical output of an optical device according to an embodiment, on the temperature variation.

FIG. 6 is a sectional drawing schematically showing an optical device according to a modification of one embodiment.

### DESCRIPTION OF EXEMPLARY EMBODIMENTS

Embodiments of the invention will now be described with references to the accompanying drawings.

### 1. STRUCTURE OF OPTICAL DEVICE

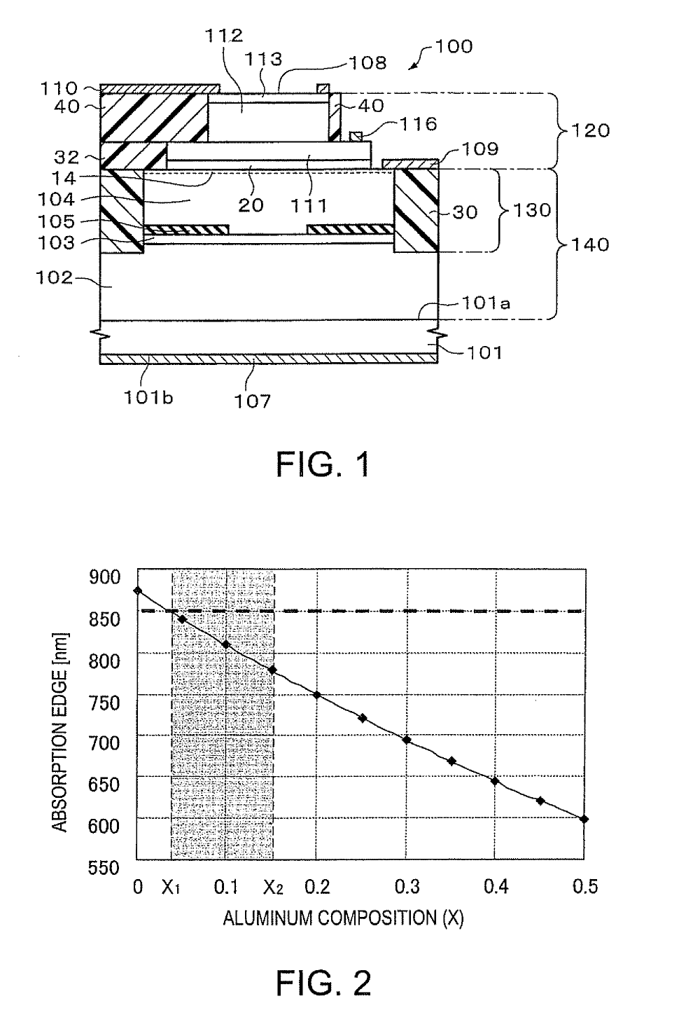

FIG. 1 is a sectional drawing illustrating an optical device 100 according to an embodiment in which the present invention is applied. As shown in FIG. 1, the optical device 100 according to this embodiment includes a substrate 101, a surface emitting semiconductor laser 140, an isolation layer 20, and a photodetection device 120. The description will now be made for the structures of the surface emitting semiconductor laser 140, and the photodetection device 120, as well as the overall structure.

### 1.1. Photodetection Device

The photodetection device 120 detects part of the laser beam emitted from the surface emitting semiconductor laser 140. The photodetection device 120 is installed on the isolation layer 20 described later. The photodetection device 120 includes a first contact layer 111, a light absorbing layer 112, a second contact layer 113, a first electrode 116, and a second electrode 110. The first contact layer 111 may have a similar plan view shape as that of the isolation layer 20.

The first contact layer 111 is formed with a semiconductor, the absorption edge wavelength thereof being smaller than the oscillation wavelength of the surface emitting semiconductor laser 140. In other words, the first contact layer 111 is formed with a semiconductor which transmits the laser light oscillated by the surface emitting semiconductor laser 140, without absorbing the laser light. The oscillation wavelength of the surface emitting semiconductor laser 140 means a wavelength of light at its maximum predicted intensity, the light being emitted from the surface emitting semiconductor laser 140.

The case in which the oscillation wavelength is 850 nm will be described as an example. In this case, the first contact layer 111 may be formed, for instance, with AlₓGa₁₋ₓAs. The Al composition “x” is preferably between 0.035 and 0.15 inclusive. The reason thereof is described using FIG. 2. FIG. 2 is a graph showing a dependency of AlₓGa₁₋ₓAs with respect to the Al composition. The horizontal axis of FIG. 2 indicates “x” in the Al composition, and the vertical axis indicates the absorption edge wavelength of AlₓGa₁₋ₓAs. According to FIG. 2, the absorption edge wavelength becomes smaller than 850 nm when the Al composition is equal to or more than x₁. Since x₁=0.035, x is preferably be equal to or more than 0.035.

The first contact layer 111 is preferably formed with materials that allow an ohmic contact with the first electrode 116. As described, in the case where the first contact layer 111 is formed with AlₓGa₁₋ₓAs, the ohmic contact is enabled between the first contact layer 111 and the first electrode 116, when x becomes approximately x₂=0.15 or less.

In other words, the first contact layer 111 is formed with an n-type (or a p-type) AlₓGa₁₋ₓAs, where x is between 0.035 and 0.15 inclusive. Consequently, the first contact layer 111 has an ohmic contact with the first electrode 116, and at the same time does not absorb the light oscillated by the surface emitting semiconductor laser 140, thereby preventing heat generation and maintaining the light-emitting property of a surface emitting semiconductor laser 140 in a favorable manner. Specifically, the first contact layer 111 is provided in a vicinity of an active layer 103 of the surface emitting semiconductor laser 140, thereby effectively inhibiting a temperature increase in a vicinity of that active layer 103.

The light absorbing layer 112 is formed on the first contact layer 111. There is no specific limitation imposed on the materials of the light absorbing layer 112, as far as the light absorbing layer 112 absorbs the light with a wavelength equivalent to that of the light oscillated by the surface emitting semiconductor laser 140. One example is a GaAs layer without impurity introduction. This allows the absorbing of light with a wavelength of 850 nm.

The second contact layer 113 is formed on the light absorbing layer 112. It is preferable that the second contact layer 113 be formed with a semiconductor having a conductivity type different from that of the first contact layer 111. At the same time, similar to the first contact layer 111, it is preferable that the semiconductor used for the second contact layer 113 have the absorption edge wavelength smaller than that of the oscillation wavelength of the surface emitting semiconductor laser 140. In the case where the oscillation wavelength of the surface emitting semiconductor laser 140 is 850 nm, the second contact layer 113 may be formed with, for instance, a p-type (or an n-type) AlₓGa₁₋ₓAs. The Al composition “x” is preferably between 0.035 and 0.15 inclusive.

The light absorbing layer 112 and the second contact layer 113 may have a similar planar shape, for instance, circular or rectangular form.

The first electrode 116 and the second electrode 110 are used for driving the photodetection device 120. The first electrode 116 is formed on the first contact layer 111, and may be formed so as to surround the light absorbing layer 112 in plan view. The first electrode 116 may have a planar shape provided with a portion leading out from the ring geometry.

The second electrode 110 is formed on the second contact layer 113. At the same time, it may have an opening and be formed in the perimeter on the second contact layer 113. This opening produces an emitting surface 108 from which the surface emitting semiconductor laser 140 emits the laser light. Moreover, portions leading out from the first electrode 116 and second electrode 110 may be formed, in order to couple themselves with electrode pads.

Moreover, insulating layers 40 and 32 may be formed around the photodetection device 120. The shapes of the insulating layers 40 and 32 are not limited to what is illustrated in FIG. 1, and may take arbitrary shapes.

### 1.2. Surface Emitting Semiconductor Laser

The surface emitting semiconductor laser 140 is formed on the substrate 101. The surface emitting semiconductor laser 140 includes a first mirror 102, an active layer 103, a second mirror 104, a current-confined path layer 105, a third electrode 107, and a fourth electrode 109. The surface emitting semiconductor laser 140 further includes a vertical cavity resonator. The first mirror 102, the active layer 103, the second mirror 104, and the current-confined path layer 105 constitute a columnar semiconductor deposit (a columnar portion 130). The columnar portion 130 functions as a resonator of the surface emitting semiconductor laser 140.

The substrate 101 is composed of, for instance, an n-type GaAs layer, The first mirror 102 is formed on the top surface 101a of the substrate 101. The first mirror 102 is composed of, for instance, a 38.5-pair multilayer mirror which is a distributed reflector, formed including n-type Al_{0.9}Ga_{0.1}As layers and n-type Al_{0.1}Ga_{0.9}As layers alternately deposited therein. Here, the substrate 101 may function as a part of the first mirror 102. The active layer 103 is formed on the first mirror 102. The active layer 103 is composed of, for instance, a GaAs well layer and an Al_{0.3}Ga_{0.7}As barrier layer, and may contain a quantum well structure in which the well layer is composed of three layers. The second mirror 104 is formed on the active layer 103. The second mirror 104 may be composed of a 24-pair multilayer mirror which is a distributed reflector, formed including p-type Al_{0.9}Ga_{0.1}As layers and p-type Al_{0.1}Ga_{0.9}As layers alternately deposited therein. No specific limitation is imposed on the composition and the number of layers constituting the first mirror 102, the active layer 103, and the second mirror 104.

The second mirror 104 is produced as p-type by, for instance, carbon (C) doping, and the first mirror 102 is produced as n-type by, for instance, silicon (Si) doping. Consequently, a pin diode is formed with the p-type second mirror 104, the undoped active layer 103, and the n-type first mirror 102.

No specific limitation is imposed on the planer shape of the columnar portion 130, and the shape may be, for instance, circular.

The current-confined path layer 105 is obtained by oxidizing the side of the AlGaAs layer that constitutes the second mirror 104, in the area close to the active layer 103. This current-confined path layer 105 is formed in the ring geometry. In other words, the sectional shape of the current-confined path layer 105 cut in a plain parallel to the substrate 101 is the ring geometry that is concentric to the circle of the columnar portion 130 in plan view.

The third electrode 107 and the fourth electrode 109 are used for driving the surface emitting semiconductor laser 140. The third electrode 107 is formed on the under surface 101b of the substrate 101. The fourth electrode 109 is formed on the second mirror 104.

Moreover, an insulating layer 30 may be formed around the columnar portion 130. The shape of the insulating layer 30 is not limited to what is illustrated in FIG. 1, and may take an arbitrary shape.

### 1.3. Isolation Layer

The optical device 100 according to this embodiment includes the isolation layer 20 on the surface emitting semiconductor laser 140. That is to say, the isolation layer 20 is provided between the surface emitting semiconductor laser 140 and the photodetection device 120. Specifically, as shown in FIG. 1, the isolation layer 20 is formed on the second mirror 104, which is, in other words, between the second mirror 104 and the first contact layer 111.

The isolation layer 20 may be formed with any one of a high resistance layer and an insulating layer. The isolation layer 20 is preferably formed with a material that transmits light oscillated by the surface emitting semiconductor laser 140, and may be formed with a semiconductor having an oscillation wavelength smaller than the absorption edge wavelength of the surface emitting semiconductor laser 140. The isolation layer 20 is formed by depositing, on the second mirror 104, an undoped semiconductor AlGaAs layer with a high Al composition, using epitaxial growth. Here, the AlGaAs layer with a high Al composition is, for instance, Al_{0.9}Ga_{0.1}As. The oxidation of the first cathode 20 is caused due to the Al contained in the isolation layer 20, and the isolation layer 20 becomes an insulating film by this oxidation.

There is no limitation imposed on the shape of the isolation layer 20, and the isolation layer 20 may have a shape similar to that of the first contact layer 111 in plan view, for instance, a circular shape. The isolation layer 20 may be larger than that of the first contact layer 111 in a planer shape.

Providing the isolation layer 20 allows an electric and optical isolation between the photodetection device 120 and the surface emitting semiconductor laser 140.

### 1.4 Overall Structure

The optical device 100 according to this embodiment includes the n-type first mirror 102 and the p-type second mirror 104 included in the surface emitting semiconductor laser 140, as well as the n-type first contact layer 111 and the p-type second contact layer 113 included in the photodetection device 120, together constituting an npnp structure.

### 2. OPERATION OF OPTICAL DEVICE

General operations of the optical device 100 according to this embodiment will now be described. Here, the drive method of the optical device 100 described hereafter is an example, and various other kinds of modifications and alternations are allowed, as long as they are within the main scope of the invention.

The photodetection device 120 has the function to monitor the output of the light generated in the surface emitting semiconductor laser 140. Specifically, the photodetection device 120 converts the light generated in the surface emitting semiconductor laser 140 into a current. The output of light generated in the surface emitting semiconductor laser 140 is detected in accordance with the values of this current. Specific description is as follows.

Applying a forward current to the pin diode with the third electrode 107 and the fourth electrode 109 causes electron-hole recombination in the active layer 103 of the surface emitting semiconductor laser 140, thereby causing a light emission. The intensity of generated light is amplified due to the stimulated emission caused by the reciprocation of light between the second mirror 104 and the first mirror 102. When the optical gain exceeds the optical loss, a laser oscillation occurs, and the laser light emits out from a bottom surface of the first mirror 102, entering into the first contact layer 111 of the photodetection device 120.

Thereafter, in the photodetection device 120, the incident light at the first contact layer 111 is transmitted therethrough and enters into the light absorbing layer 112. Part of this incident light is absorbed by the light absorbing layer 112, thereby causing an optical pumping, generating electrons and holes. Electrons move to the first electrode 116 and holes move to the second electrode 110, due to the electric field applied from the exterior of the optical device 100, thereby causing a current (optical current). Measuring the value of this current allows detection of an optical output of the surface emitting semiconductor laser 140.

The optical output of the surface emitting semiconductor laser 140 is determined mainly by a bias voltage applied to the surface emitting semiconductor laser 140. Specifically, the optical output of the surface emitting semiconductor laser 140 significantly changes, depending on the active layer temperature or a lifetime of the surface emitting semiconductor laser 140. Therefore, since the semiconductors used in the first contact layer 111 as well as in the second contact layer 113 have the absorption edge wavelength smaller than the oscillation wavelength of the surface emitting semiconductor laser 140 as described above, the active layer temperature increase is inhibited in the surface emitting semiconductor laser 140. Therefore, the optical output of the surface emitting semiconductor laser 140 is maintained in a constant value.

In the optical device 100 according to this embodiment, the value of the current flowing inside the surface emitting semiconductor laser 140 is adjusted by monitoring the optical output of the surface emitting semiconductor laser 140, and by adjusting the value of a voltage applied thereto based on the value of the current generated in the photodetection device 120. An external electronic circuit (un-illustrated drive circuit) carries out the feed back control of the optical output of the surface emitting semiconductor laser 140, into a voltage applied to the surface emitting semiconductor laser 140.

### 3. MANUFACTURING METHOD OF OPTICAL DEVICE

An example of a manufacturing method of the optical device 100 according to an embodiment to which the aspects of the invention are applied will now be described.

(1) A semiconductor multilayer film is first formed on the top surface 101a of the substrate 101 formed with the n-type GaAs layers by epitaxial growth while modulating the composition of the constituting layers. Here, an example of components included in the semiconductor multilayer film includes: the first mirror 102 in which the n-type Al_{0.9}Ga_{0.1}As layers and the n-type Al_{0.1}Ga_{0.9}As layers are alternately deposited; the active layer 103 composed of the GaAs well layer and the Al_{0.3}Ga_{0.7}As barrier layer, the well layer including the quantum well structure in which the well layer is composed of three layers; and the 24-pair second mirror 104 in which the p-type Al_{0.9}Ga_{0.1}As layers and the p-type Al_{0.1}Ga_{0.9}As layers are alternately deposited; the isolation layer 20 composed of Al_{0.9}Ga_{0.1}As; the first contact layer 111 composed of the n-type Al_{0.12}Ga_{0.88}As; the light absorbing layer 112 composed of the undoped GaAs layer; and the second contact layer 113 composed of the p-type Al_{0.12}Ga_{0.88}As. The semiconductor multilayer film is formed by sequentially depositing those layers on the substrate 101.

During the growth of the second mirror 104, at least one layer in the vicinity of the active layer 103 is formed into the AlAs layer or AlGaAs layer which is to be oxidized to be formed into the current-confined path layer 105. The Al composition of the AlGaAs layer which will become the current-confined path layer 105 is, for instance, greater than or equal to 0.95 or more. In this embodiment, the Al composition of the AlGaAs layer means the composition of aluminum (Al) with respect to group 3 elements. The value of the Al composition of the AlGaAs layer is between 0 and 1 inclusive. In other words, the AlGaAs layer includes the GaAs layer (where the Al composition is “0”) and the AlAs layer (where the Al composition is “1”).

A top layer 14 of the second mirror 104 is preferably an AlGaAs layer with the Al composition of 0.3 or less, for instance, a p-type Al_{0.1}Ga_{0.9}As layer.

The temperature for carrying out the epitaxial growth is optionally determined in accordance with a growing method, types of raw material and the substrate 101, as well as the variation, thickness, and carrier concentration of the semiconductor multilayer film. Generally, a range between 450° C. to 800° C. inclusive is preferable. The time required for the epitaxial growth is also optionally determined in a manner similar to determining the temperature. Method of epitaxial growth includes: metal-organic vapor phase epitaxy (MOVPE), molecular beam epitaxy (MEB), and liquid phase epitaxy (LPE).

(2) Subsequently, using the known lithography and etching techniques, the semiconductor multilayer film is patterned into a desired configuration. Consequently, the columnar portion 130, the isolation layer 20, and the first contact layer 111 are formed, as well as the light absorbing layer 112 and the second contact layer 113. There is no specific limitation imposed on the order of formation of each layer in this patterning process.

Since the isolation layer 20 is composed of the Al_{0.9}Ga_{0.1}As layer, a selective etching of the isolation layer 20 over the top layer 14 is possible. For instance, it is possible to slow down the etching speed of the top layer 14 of the second mirror 104 by using etchants such as diluted hydrofluoric acid (HF+H₂O) and buffered hydrofluoric acid (NH₄F+H₂O).

(3) The substrate 101 is then fed into a water vapor atmosphere at approximately, for instance, 400° C., thereby oxidizing, from the sides, the layers with the high Al composition in the second mirror 104 and the isolation layer 20 included in the second mirror 104.

The oxidation rate depends on the temperature of a furnace, the amount of supplied water vapor, and the Al composition as well as film thickness of the layer to be oxidized. In the surface emitting semiconductor laser 140 provided with the current-confined path layer 105 formed by oxidation, the current flows, when the optical device 100 is driven, only in the part in which the current-confined path layer 105 is not formed (not oxidized). Consequently, the current density can be controlled, in the process of forming the current-confined path layer 105 with oxidation, by controlling the size of the area in which the current-confined path layer 105 is to be formed. It is preferable that the film thickness of the isolation layer 20 be thicker than the film thickness defined for forming the current-confined path layer 105.

(4) Subsequently, the first electrode 116, the second electrode 110, the third electrode 107, and the fourth electrode 109 are formed. Specific description is as follows.

Prior to forming those electrodes, areas in which electrodes are to be formed are cleaned if necessary, by using a process such as plasma treatment. This allows the forming of devices with higher stability.

Thereafter, an un-illustrated single layer or multilayer film is formed with a conductive material for electrode with a method such as vacuum deposition. Electrodes are then formed in the desired regions by removing the multilayer film present in areas excluding the prescribed positions, using a known liftoff technique.

Annealing is then carried out as necessary, for instance, in a nitrogen atmosphere. The temperature of annealing is carried out at, for instance, 400° C. The duration of annealing is, for instance, approximately three minutes.

These processes may be carried out individually for each electrode, or, simultaneously for a plurality of electrodes. The second electrode 110 and the fourth electrode 109 are formed with a laminate of, for instance, alloy of gold (Au) and germanium (Ge), and gold (Au). The first electrode 116 and the third electrode 107 are formed with a laminate of, for instance, platinum (Pt), titanium (Ti), and gold (Au). Materials for electrodes are not limited to the above. Other known metals, alloys, and laminates thereof may be used.

The optical device 100 according to this embodiment is therefore obtained with the processes described above.

### 4. EXAMPLES

A reverse bias voltage of 3V was applied on the optical device manufactured using the manufacturing method according to this embodiment, so as to measure the monitor current from the photodetection device as well as the temperature of the active layer in the surface emitting semiconductor laser. The measurements were carried out in a case in which the n-type Al_{0.12}Ga_{0.88}As was employed as the first contact layer, as well as in a comparative example in which the n-type GaAs layer was employed.

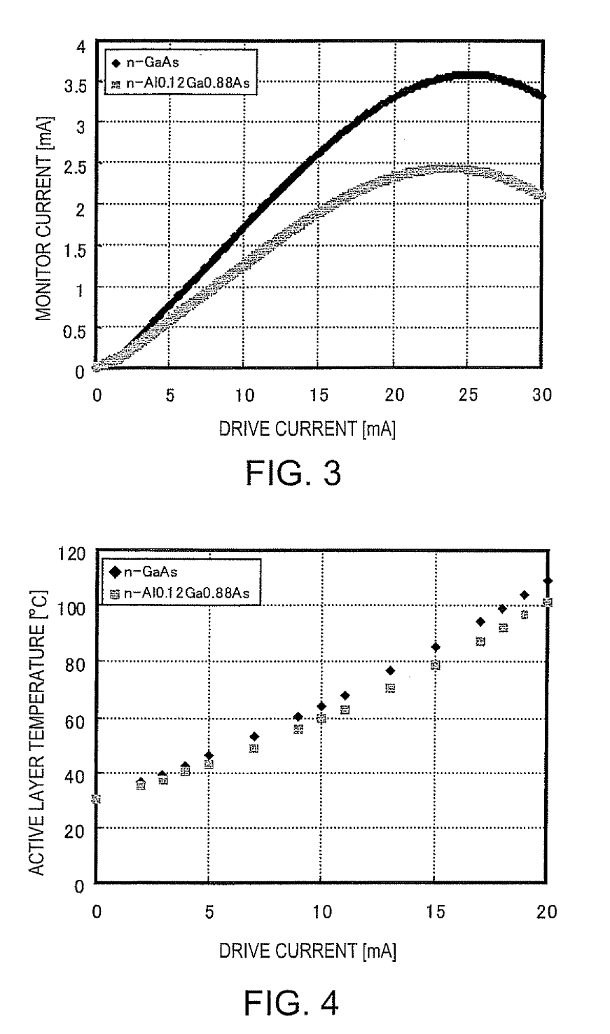

FIG. 3 is a graph indicating the monitor current characteristics, and FIG. 4 is a graph indicating the active layer temperature of the surface emitting semiconductor laser. Referring to FIG. 3, the horizontal axis indicates a drive current of the surface emitting semiconductor laser, and the vertical axis indicates a monitor current value detected by the photodetection device. According to FIG. 3, it was confirmed that by employing the n-type Al_{0.12}Ga_{0.88}As layer as the first contact layer, the amount of light absorption was reduced compared to the case of employing the n-type GaAs layer.

Referring now to FIG. 4, the horizontal axis indicates a drive current of the surface emitting semiconductor laser, and the vertical axis indicates an active layer temperature. According to FIG. 4, it was confirmed that by employing the n-type Al_{0.12}Ga_{0.88}As layer as the first contact layer, the increase in the active layer temperature was suppressed compared to the case of employing the n-type GaAs layer.

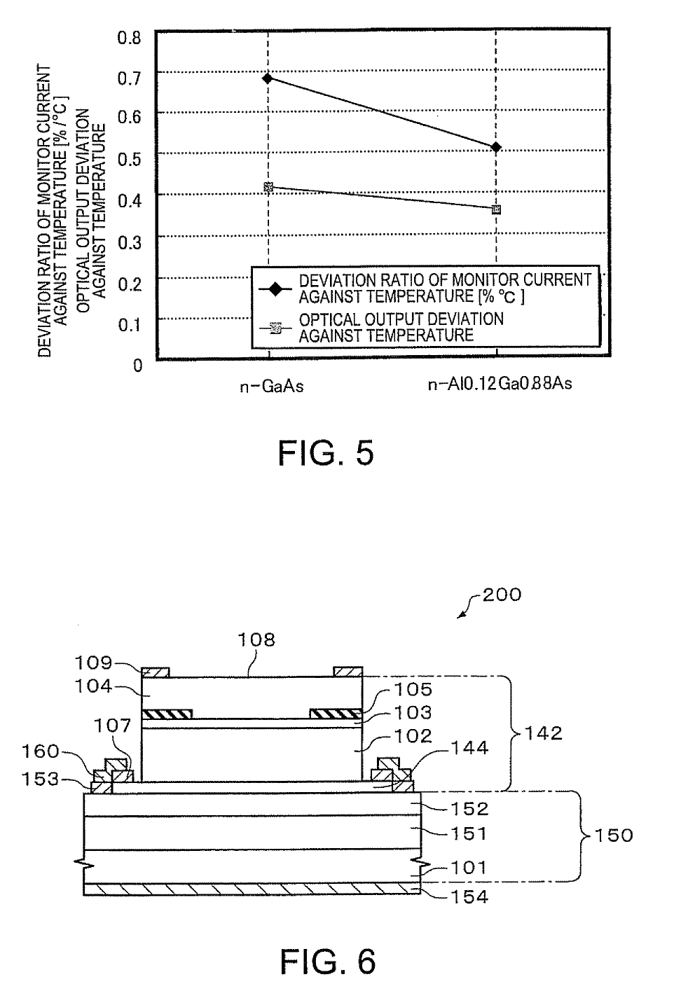

Moreover, the reverse bias voltage of 3V was applied on the optical device manufactured using the manufacturing method according to this embodiment, so as to measure, with respect to the ambient temperature, the deviation of the monitor current detected by the photodetection device as well as that of the optical output of the surface emitting semiconductor laser. The measurements were carried out in a case in which the n-type Al_{0.12}Ga_{0.88}As was employed as the first contact layer, as well as in a comparative example in which the n-type GaAs layer was employed. FIG. 5 is a graph indicating the dependency of the monitor current and of the optical output on the ambient temperature deviation. According to FIG. 5, it was confirmed that by employing the n-type Al_{0.12}Ga_{0.88}As layer as the first contact layer, the deviations of the monitor current, as well as that of the optical output with respect to the ambient temperature, were suppressed compared to the case of employing the n-type GaAs layer.

### 5. MODIFICATION

A modification of the embodiment will now be described using FIG. 6. While the optical device 100 described above includes the photodetection device 120 formed superjacent to the surface emitting semiconductor laser 140, the optical device 200 according to the modification being different in that it includes the photodetection device 150 formed to be subjacent to the surface emitting semiconductor laser 140. The structure of the optical device 200 will now be described.

FIG. 6 is a sectional drawing schematically illustrating the optical device 200 according to the modification. The optical device 200 includes the photodetection device 150 and a surface emitting semiconductor laser 142. The photodetection device 150 and the surface emitting semiconductor laser 142 will now be described.

### 5.1. Photodetection Device

The photodetection device 150 detects part of the laser light emitted from the surface emitting semiconductor laser 142. The photodetection device 150 includes the second contact layer (substrate) 101, a light absorbing layer 151, a first contact layer 152, and a first electrode 153.

The substrate 101 is formed with, for instance, the n-type GaAs layer. The light absorbing layer 151 is formed on the second contact layer 101. There is no specific limitation imposed on the materials of the light absorbing layer 151, as far as the light absorbing layer 112 absorbs the light with a wavelength equivalent to that of the light oscillated by the surface emitting semiconductor laser 142. An example is a GaAs layer without impurity introduction. This allows the absorbing of the light with wavelength of 850 nm.

The first contact layer 152 is formed with a semiconductor, the absorption edge wavelength thereof being smaller than the oscillation wavelength of the surface emitting semiconductor laser 142. In other words, the first contact layer 152 is formed with a semiconductor which transmits the laser light oscillated by the surface emitting semiconductor laser 142, without absorbing the laser light.

As an example, the case in which the oscillation wavelength is 850 nm will be described. In this case, the first contact layer 152 may be formed, for instance, with AlₓGa₁₋ₓAs. The Al composition “x” is preferably between 0.035 and 0.15 inclusive.

The first contact layer 152 is preferably formed with a semiconductor having a conductivity type different from that of the second contact layer 101, as well as with the material that allows an ohmic contact with the first electrode 153. As described, in the case where the first contact layer 152 is formed with AlₓGa₁₋ₓAs, the ohmic contact is enabled between the first contact layer 152 and the first electrode 153, when x becomes approximately x₂=0.15 or less. The first contact layer 152 is formed in p-type by, for instance, carbon (C) doping.

In other words, the first contact layer 152 is formed with the p-type (or n-type) AlₓGa₁₋ₓAs, where x is between 0.035 and 0.15 inclusive. Consequently, the first contact layer 152 has an ohmic contact with the first electrode 153, and at the same time does not absorb the light oscillated by the surface emitting semiconductor laser 142, thereby preventing heat generation and maintaining the light-emitting property of a surface emitting semiconductor laser 142 in a favorable manner.

The first electrode 153 and the second electrode 154 are used for driving the photodetection device 150. The first electrode 153 is formed on the first contact layer 152, and the first electrode 153 may have a planar shape provided with a portion leading out from the ring geometry. The second electrode 154 is formed on a bottom surface of the second contact layer 101.

### 5.2. Surface Emitting Semiconductor Laser

The surface emitting semiconductor laser 142 is formed on the first contact layer 152. The surface emitting semiconductor laser 142 includes a third contact layer 144, a first mirror 102, the active layer 103, the second mirror 104, the current-confined path layer 105, the third electrode 107, and the fourth electrode 109.

The third contact layer 144 is formed on the first contact layer 152, and is formed with, for instance, the n-type GaAs layer. The first mirror 102 is formed on the third contact layer 144, and is made up of, for instance, the 38.5-pair multilayer mirror which is a distributed reflector, formed including the n-type Al_{0.9}Ga_{0.1}As layers and the n-type Al_{0.1}Ga_{0.9}As layers alternately deposited therein.

The active layer 103 is formed on the first mirror 102. The active layer 103 is composed of, for instance, a GaAs well layer and an Al_{0.3}Ga_{0.7}As barrier layer, and may contain a quantum well structure in which the well layer is composed of three layers. The second mirror 104 is formed on the active layer 103. The second mirror 104 may be made up of a 24-pair multilayer mirror which is a distributed reflector, formed including p-type Al_{0.9}Ga_{0.1}As layers and p-type Al_{0.1}Ga_{0.9}As layers alternately deposited therein. No specific limitation is imposed on the composition and the number of layers constituting the first mirror 102, the active layer 103, and the second mirror 104.

The second mirror 104 is produced in p-type by, for instance, carbon (C) doping, and the first mirror 102 is produced in n-type by, for instance, silicon (Si) doping. Consequently, a pin diode is formed with the p-type second mirror 104, the undoped active layer 103, and the n-type first mirror 102.

No specific limitation is imposed on the planer shape of the columnar portion 130, and the shape may be, for instance, circular.

The current-confined path layer 105 is obtained by oxidizing the side of the AlGaAs layer that constitutes the second mirror 104, in the area close to the active layer 103. This current-confined path layer 105 is formed in the ring geometry.

The third electrode 107 and the fourth electrode 109 are used for driving the surface emitting semiconductor laser 140. The third electrode 107 is formed on the third contact layer 144. The fourth electrode 109 is formed on the second mirror 104. At the same time, it has a shape of a ring geometry and may have an opening that forms the emitting surface 108.

A common electrode 160 is formed on the top surface of the third electrode 107 and the first electrode 153.

### 5.3. Overall Structure

The optical device 200 according to this modification includes the second contact layer 101 and the first contact layer 152 included in the photodetection device 150, as well as the third contact layer 144, the first mirror 102, and the second mirror 104, together constituting the npnp structure. The photodetection device 150 functions as the pin photo diode.

### 5.4. Operation of Optical Device

In the optical device 200 according to the modification, the surface emitting semiconductor laser 142 emits light from both the top and the bottom surfaces. The photodetection device 150 has the function to monitor the light emitted from the bottom surface of the surface emitting semiconductor laser 142. The specific detecting operation of the photodetection device 150 is similar to that of the photodetection device 120 described above, and therefore the description thereof is omitted.

Above is the structure of the optical device 200 according to the modification. Structures and the manufacturing method other than the above are shared with those of the optical device 100, and therefore the description is omitted.

6. The present invention shall not be limited to the content of the embodiments described above, and may include various modifications. For instance, included within a scope of the invention is a structure substantially identical to those described in the embodiments, such as a structure with identical function, method, and resulting effect thereof as that of the embodiments, and, a structure with identical purpose and resulting effect thereof. Moreover, the invention also includes, within the scope thereof, a structure in which a portion not essential to the structures described in the embodiments is replaced with an alternative portion. The invention further includes, within the scope thereof, a structure which exhibits an identical effect as the one described in the embodiments, as well as a structure which achieves an identical purpose as the one described in the embodiments. Still further, the invention includes, within the scope thereof, a structure to which known techniques are applied is added to the structures described in the embodiments.

What is claimed is:

1. An optical device, comprising:
a surface emitting semiconductor laser; and
a photodetection device for detecting part of laser light emitted from the surface emitting semiconductor laser,
the photodetection device including a light absorbing layer and a first contact layer, and
the first contact layer being formed with a semiconductor having an absorption edge wavelength smaller than an oscillation wavelength of the surface emitting semiconductor laser.

2. The optical device according to claim 1, wherein the first contact layer is provided closer to the surface emitting semiconductor laser relative to the light absorbing layer.

3. The optical device according to claim 1, wherein:
the photodetection device further includes a second contact layer provided facing the first contact layer, having the light absorbing layer therebetween; and
the second contact layer is formed with a semiconductor having the absorption edge wavelength thereof being smaller than the oscillation wavelength of the surface emitting semiconductor laser.

4. The optical device according to claim 1, wherein:
the photodetection device further includes an electrode in contact with the first contact layer; and
the first contact layer is formed with a material allowing an ohmic contact with the electrode.

5. The optical device according to claim 1, wherein the first contact layer is formed with aluminum gallium arsenide (AlGaAs) if the oscillation wavelength of the surface emitting semiconductor laser is 850 nm.

6. The optical device according to claim 5, wherein the first contact layer is formed with AlₓGa₁₋ₓAs, where x is greater than or equal to 0.035.

7. The optical device according to claim 5, wherein the first contact layer is formed with AlₓGa₁₋ₓAs, where x is between 0.035 and 0.15 inclusive.

8. The optical device according to claim 1, wherein:
the surface emitting semiconductor laser includes:
a first mirror formed superjacent to the surface emitting semiconductor laser;
an active layer formed superjacent to the first mirror; and
a second mirror formed superjacent to the active layer; and
the photodetection device includes:
the first contact layer formed superjacent to the second mirror;
the light absorbing layer formed superjacent to the first contact layer; and
a second contact layer formed superjacent to the light absorbing layer.

9. The optical device according to claim 1, further comprising an isolation layer formed between the surface emitting semiconductor laser and the photodetection device, the isolation layer containing a semiconductor having the absorption edge wavelength smaller than the oscillation wavelength of the surface emitting semiconductor laser.

10. The optical device according to claim 1, wherein:
the photodetection device includes:
a second contact layer;
the light absorbing layer formed superjacent to the second contact layer; and
the first contact layer formed superjacent to the light absorbing layer; and
the surface emitting semiconductor laser includes:
the first mirror formed superjacent to the first contact layer;
the active layer formed superjacent to the first mirror; and
the second mirror formed superjacent to the active layer.

11. An optical device, comprising:
a surface emitting semiconductor laser; and
a photodetection device for detecting part of laser light emitted from the surface emitting semiconductor laser;
the photodetection device including a light absorbing layer and a first contact layer; and
the first contact layer being formed with a semiconductor transparent to an oscillation wavelength of the surface emitting semiconductor laser.

12. A method for manufacturing an optical device including a surface emitting semiconductor laser and a photodetection device for detecting part of laser light emitted from the surface emitting semiconductor laser, the method comprising:
forming the surface emitting semiconductor laser;
forming a first contact layer for constituting the photodetection device, using a semiconductor having an absorption edge wavelength smaller than an oscillation wavelength of the surface emitting semiconductor laser; and
forming a light absorbing layer, using a semiconductor which absorbs light from the surface emitting semiconductor laser.
